(19) United States
(12) Patent Application Publication
(10) Pub. No.: US 2019/0272989 A1
(43) Pub. Date: Sep. 5, 2019

(54) METHOD AND APPARATUS FOR MANUFACTURING SEMICONDUCTOR DEVICE

(71) Applicant: TOSHIBA ELECTRONIC DEVICES & STORAGE CORPORATION, Tokyo (JP)

(72) Inventors: YASUHIRO ISOBE, Kanazawa Ishikawa (JP); NAOHARU SUGIYAMA, Yokohama Kanagawa (JP); Takayuki SAKAI, Chofu Tokyo (JP); Kyoichi Suguro, Yokohama Kanagawa (JP)

(73) Assignee: TOSHIBA ELECTRONIC DEVICES & STORAGE CORPORATION, Tokyo (JP)

(21) Appl. No.: 16/112,437

(22) Filed: Aug. 24, 2018

(30) Foreign Application Priority Data
Mar. 2, 2018 (JP) 2018-037659

(51) Int. Cl. H01L 21/02; H01L 21/67; H01L 21/687; H01J 37/32; C23C 16/30; C23C 16/50

(52) U.S. Cl. CPC H01L 21/0254; H01L 21/0262; H01L 21/67017; H01L 21/68714; H01J 2237/3321; C23C 16/303; C23C 16/50; H01J 2237/327; H01J 37/3244

(57) ABSTRACT

According to one embodiment, a method of manufacturing a semiconductor device includes generating a plasma of a first gas containing a nitrogen gas and an ammonia gas, supplying a second gas containing nitrogen-containing radicals produced by generating the plasma of the first gas, to a substrate, supplying an organic metal gas containing a group III metallic element to the substrate, and forming a group III nitride semiconductor layer on the substrate by the second gas and the organic metal gas.

### CROSS-REFERENCE TO RELATED APPLICATIONS

This application is based upon and claims the benefit of priority from Japanese Patent Application No. 2018-037659, filed Mar. 2, 2018, the entire contents of which are incorporated herein by reference.

### FIELD

Embodiments described herein relate generally to a method and apparatus for manufacturing a semiconductor device.

### BACKGROUND

One of methods of forming a group III nitride semiconductor layer is a method using a high-concentration ammonia gas. This method enables high-speed growth of the group III nitride semiconductor layer, but increases material costs and equipment costs.

In contrast, an example of a method of forming a group III nitride semiconductor layer without using an ammonia gas is a method of generating a plasma of a gas mixture of a nitrogen gas and a hydrogen gas and producing nitrogen-containing radicals necessary to form the group III nitride semiconductor layer. However, since the bond dissociation energy of nitrogen molecule is very large, this method cannot supply a sufficient quantity of nitrogen-containing radicals to a substrate and can hardly make the group III nitride semiconductor layer grow up at a high speed.

### BRIEF DESCRIPTION OF THE DRAWINGS

FIG. 1 is an illustration showing a schematic structure of a manufacturing apparatus of a semiconductor device according to the embodiments.

FIG. 2 is a cross-sectional view showing an example of a group III nitride semiconductor layer formed by a method of manufacturing a semiconductor device according to the embodiments.

FIG. 3 is an illustration for explanation of preconditions of simulations of the method of manufacturing a semiconductor device according to the embodiments.

FIG. 4 is a table showing results of the simulations of the method of manufacturing a semiconductor device according to the embodiments.

### DETAILED DESCRIPTION

In general, according to one embodiment, a method of manufacturing a semiconductor device includes generating a plasma of a first gas containing a nitrogen gas and an ammonia gas, supplying a second gas containing nitrogen-containing radicals produced by generating the plasma of the first gas, to a substrate, supplying an organic metal gas containing a group III metallic element to the substrate, and forming a group III nitride semiconductor layer on the substrate by the second gas and the organic metal gas.

Embodiments will be described hereinafter with reference to the accompanying drawings.

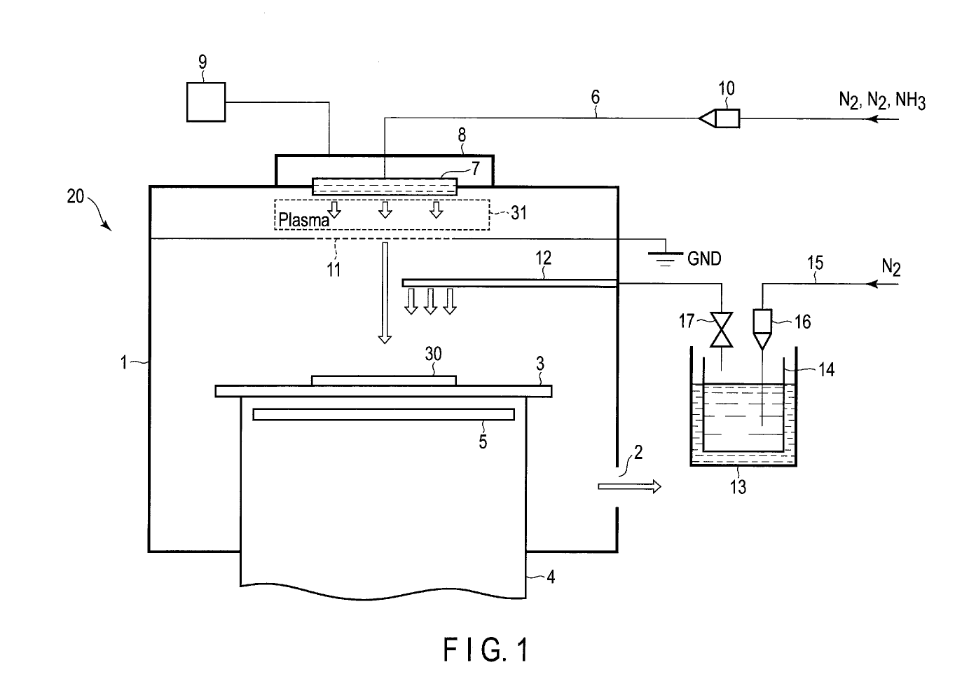

FIG. 1 is an illustration showing a schematic structure of a manufacturing apparatus of a semiconductor device (metal organic chemical vapor deposition (MOCVD) apparatus with a plasma source) 20 according to the embodiments.

The manufacturing apparatus of the semiconductor device 20 includes a chamber 1, an exhaust port 2, a susceptor 3, a rotary mechanism body 4, a heater 5, a first gas supply tube 6, a shower head nozzle 7, a matching box 8, a high frequency power source (radio frequency (RF) power source) unit 9, a mass flow controller 10, a mesh-like member 11, a second gas supply tube 12, a constant temperature bath 13, a vessel 14, a third gas supply tube 15, a mass flow controller 16, and a needle valve 17.

The chamber 1 includes an exhaust port 2. The susceptor 3 is disposed on the rotary mechanism body 4. In addition, a substrate 30 is placed on the susceptor 3. The heater 5 aims to heat the substrate 30 on the susceptor 3.

The first gas supply tube 6 supplies a first gas into the chamber 1. The first gas contains a nitrogen gas, a hydrogen gas, and an ammonia gas. The first gas may contain at least the nitrogen gas and the ammonia gas and may not contain the hydrogen gas. The concentration of the ammonia gas in the first gas is desirably 1% to 10%. The flow of the first gas is controlled by the mass flow controller 10.

The shower head nozzle 7 is connected to the first gas supply tube 6. Plural holes are formed in the shower head nozzle 7, and the first gas supplied through the holes. In addition, the shower head nozzle 7 also functions as an electrode supplied with electric power to generate a plasma of the first gas supplied from the first gas supply tube 6. The shower head nozzle 7 is used as one parallel plate type electrode. The shower head nozzle 7 is connected to the high frequency power source (RF power source) unit 9 via a matching box 8.

The high frequency power source (RF power source) unit 9 supplies a high frequency power to the shower head nozzle 7. The plasma of the first gas can be thereby generated. The high frequency power source (RF power source) unit 9 is, for example, a high frequency power source which supplies a sine wave high frequency voltage higher than or equal to 60 MHz or a pulse-like high frequency voltage higher than or equal to 60 MHz. By using such a high frequency power source, the density of electrons in the plasma becomes high and a number of nitrogen-containing radicals can be supplied onto the substrate 30.

A plasma generation mechanism includes the shower head nozzle 7, the matching box 8, and the high frequency power source (RF power source) unit 9. A first gas supply unit includes the first gas supply tube 6 and the shower head nozzle 7.

The plasma is generated in a plasma generation region 31. The plasma generation region 31 is located under the shower head nozzle 7, at a position remoter from the substrate 30 than a position of the second gas supply tube 12. In the plasma generation region 31, the plasma density is high and the temperature is high. For this reason, a metal or alloy having a melting point of 700° C. or higher is used for the shower head nozzle 7.

When the plasma of the first gas is generated, a second gas containing nitrogen-containing radicals is produced. More specifically, the nitrogen-containing radical is N radical, NH radical, NH₂ radical, NH₃ radical, or the like. In addition, the second gas contains not only the nitrogen-containing radicals, but also H radicals and electrons.

The mesh-like member 11 is disposed between the shower head nozzle 7 (plasma generation region 31) and a position of an exit of the second gas supply tube 12. The mesh-like member 11 is a metal member or an insulator-coated metal member and is grounded. Since the mesh-like member 11 is disposed, the generated plasma is confined on an upper side than the mesh-like member 11. In addition, the mesh-like member 11 includes a number of through-holes, and the second gas is supplied onto the substrate 30 through the through-holes.

The second gas supply tube (second gas supply unit) 12 supplies an organic metal gas containing a group III metallic element to the substrate 30. The organic metal gas contains at least one of aluminum, gallium, or indium. The constant temperature bath 13 is disposed outside the chamber 1. The vessel 14 is disposed in the constant temperature bath 13, and trimethyl gallium, trimethyl aluminum, or trimethyl indium is contained in the vessel 14. In the following explanations, trimethyl gallium is assumed to be contained in the vessel 14.

The third gas supply tube 15 is disposed to supply a nitrogen gas into the vessel 14. Supply of the nitrogen gas is controlled by the mass flow controller 16. Liquid trimethyl gallium is evaporated by bubbling with the nitrogen gas, and the organic metal gas containing gallium is supplied into the chamber 1 through the second gas supply tube 12. The amount of supply of the organic metal gas is controlled by the needle valve. An automatic pressure controller may be used instead of the needle valve. The organic metal gas is thus supplied onto the substrate 30.

The substrate 30 placed on the susceptor 3 is supplied with the organic metal gas supplied through the second gas supply tube 12 and the second gas containing the nitrogen-containing radicals produced by generating the plasma of the first gas.

A method of forming the group III nitride semiconductor layer using the above-explained manufacturing apparatus of the semiconductor device will be explained below.

The first gas containing the nitrogen gas, the hydrogen gas, and the ammonia gas is supplied into the chamber 1 through the first gas supply tube 6. As explained above, the first gas may not contain the hydrogen gas. The concentration of the ammonia gas in the first gas is 1% to 10%.

The plasma of the first gas is generated by supplying the high frequency power from the high frequency power source (RF power source) unit 9 to the shower head nozzle 7. The second gas containing the nitrogen-containing radicals is produced by generating the plasma. As explained above, the plasma of the first gas is generated at a position remoter from the substrate 30 than the position where the organic metal gas is supplied to the substrate 30 (i.e., the position of the exit of the second gas supply tube 12). The nitrogen-containing radicals contain N radical, NH radical, NH₂ radical, and NH₃ radical. The second gas contains not only the nitrogen-containing radicals, but also H radicals, electrons, and the like.

Then, the second gas containing the produced nitrogen-containing radicals is supplied onto the substrate 30. The second gas is supplied onto the substrate 30 through the through holes of the mesh-like member 11 disposed between the plasma generation region 31 and the position where the organic metal gas is supplied to the substrate 30 (i.e., the position of the exit of the second gas supply tube 12).

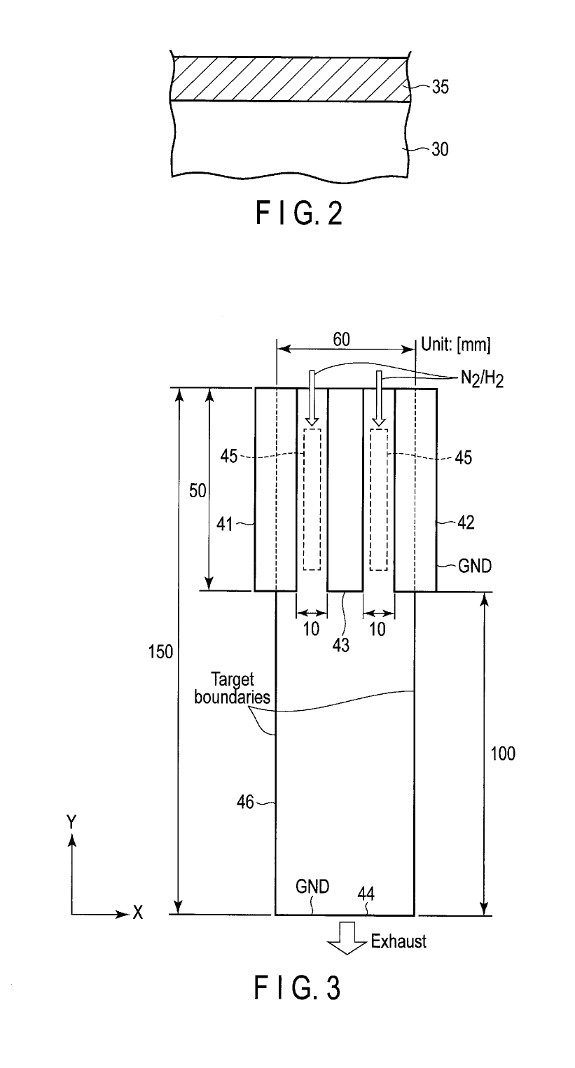

In addition, the organic metal gas (for example, trimethyl gallium) containing the group III metallic element is supplied onto the substrate 30 from the second gas supply tube 12. Then, the group III nitride semiconductor layer is formed on the substrate 30 by the supplied the second gas and the organic metal gas. More specifically, epitaxial growth of a GaN layer can be generated by making the nitrogen-containing radicals in the second gas and a trimethyl gallium gas react with each other on the substrate 30. A GaN layer 35 is thus formed on the substrate 30 as shown in FIG. 2.

When the group III nitride semiconductor layer is formed on the substrate 30, a growth temperature of the semiconductor layer is desirably below 1000° C. More desirably, the growth temperature is 900° C. or less. The growth temperature means a temperature of the substrate 30 (temperature of a surface of the substrate 30). In addition, the pressure is desirably 100 Pa to 10 kPa.

If the rate of the ammonia gas to the first gas is too small, the quantity of the nitrogen-containing radicals supplied onto the substrate 30 is reduced and improvement of the growth rate of the semiconductor layer cannot be sufficiently attempted. On the other hand, if the rate of the ammonia gas to the first gas is too high, the density of electrons produced in the generation of the plasma of the first gas is small. For example, if the ratio of the ammonia gas in the first gas is 30% or more, the density of electrons reduced in the plasma generation. As a result, the supply of the nitrogen-containing radicals onto the substrate 30 may be reduced. Therefore, if the rate of the ammonia gas in the first gas is too high, improvement of the growth rate of the semiconductor layer may be suppressed. For this reason, in the embodiments, the ammonia gas is contained in the first gas such that a quantity of the ammonia gas does not greatly vary the density of the electrons in the plasma generation.

Thus, if the plasma of the first gas is generated, the quantity of the nitrogen-containing radicals supplied onto the substrate 30 can be increased since an appropriate quantity of the ammonia gas is contained in the first gas. The growth rate of the semiconductor layer can be thereby improved.

The simulation results will be explained below.

FIG. 3 is an illustration for explanation of preconditions of simulations of method of manufacturing a semiconductor device according to the embodiments. Supply of a gas mixture of nitrogen and hydrogen and supply of a gas formed by adding the appropriate quantity of the ammonia gas to the gas mixture were simulated under the following conditions, and the density of the nitrogen-containing radicals on the substrate was estimated.

In FIG. 3, electrodes 41 and 42 were grounded and a high frequency power was supplied to an electrode 43.

As shown in FIG. 3, the length between target boundaries is 60 mm. The distance between the electrodes 43 and 41 and the distance between the electrodes 43 and 42 were 10 mm. The length of each of the electrodes 41, 42, and 43 in the longitudinal direction was 50 mm. The distance from an end of the electrodes 41, 42, and 43 closer to a substrate 44, to the substrate 44, was 100 mm, and the distance from an end of the electrodes 41, 42, and 43 remoter from the substrate 44, to the substrate 44, was 150 mm. The frequency range of the high frequency power supplied to the electrode 43 was 60 to 100 MHz. The pressure inside a chamber 46 was 100 Pa. In addition, RF power of 1 kW was supplied to the structure shown in FIG. 3.

Deactivation of the radicals on the wall surface was considered in the simulations. In addition, the reflectances of N radical and H radical on the wall surface were 90% and 95%, respectively. Furthermore, the secondary electron emission ratio was assumed to be γ=0.1.

A simulation using a gas mixture of nitrogen and hydrogen (N₂:H₂=10:6) as a supply gas for supplying the nitrogen-containing radicals onto the substrate 44 was executed and another simulation using a first gas containing the nitrogen gas, the hydrogen gas, and the ammonia gas (N₂:H₂:NH₃=10:5.4:0.6; NH₃ in the first gas was approximately 3.7%) as the supply gas for supplying the nitrogen-containing radicals onto the substrate 44 was executed.

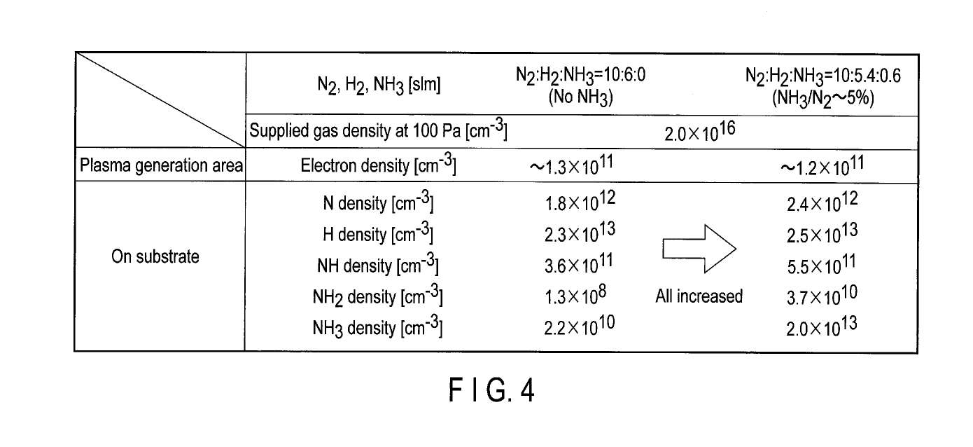

The simulation results obtained by executing the simulations under the above conditions are shown in FIG. 4.

A supplied gas density at 100 Pa was 2.0×10¹⁶ cm⁻³ in the gas mixture of nitrogen and hydrogen, and the first gas containing the nitrogen gas, the hydrogen gas, and the ammonia gas.

The electron density of a plasma generation region 45 was 1.3×10¹¹ cm⁻³ when the gas mixture was used, and 1.2×10¹¹ cm⁻³ when the first gas was used. That is, the density of electrons was not greatly varied in the gas mixture and the first gas when the plasma was generated. It is therefore considered that the first gas contained the ammonia gas such that the quantity of the ammonia gas did not vary the density of the electrons when the plasma was generated.

The density of each of N radicals, H radicals, NH radicals, NH₂ radicals, and NH₃ radicals on the substrate 44 was increased when the first gas was used as compared with the density of them when the gas mixture was used. In particular, the density of N radicals was increased by 30% or more as compared with the density when the gas mixture was used.

Therefore, similarly to the embodiments, the density of the nitrogen-containing radicals on the substrate can be increased as compared with the density in the case of generating the plasma of the gas mixture of nitrogen and hydrogen, by making the gas mixture of N₂ gas and H₂ gas contain the appropriate quantity (approximately 3.7% in the above-explained simulation) of the ammonia gas. That is, the density of each of N radicals, NH radicals, NH₂ radicals, and NH₃ radicals, which are the nitrogen-containing radicals, is increased. In particular, the density of N radicals on the substrate can be increased by approximately 30%. The approximate quantity indicates a quantity which does not greatly vary the density of electrons when the plasma of the first gas containing the ammonia gas is generated as compared with the density of electrons in the case of generating the plasma of the gas mixture of nitrogen and hydrogen as explained above.

Thus, the growth rate of the group III nitride semiconductor layer can be increased by 30% or more by making the first gas contain the approximate quantity of the ammonia gas. Furthermore, the quality of the group III nitride semiconductor layer, which is at least more than or equivalent to the quality in the case of using the gas mixture of nitrogen and hydrogen can be secured.

According to the method of forming an III group nitride semiconductor layer by generating the plasma of the gas mixture of nitrogen and hydrogen and supplying the nitrogen-containing radicals produced by generating the plasma, onto the substrate 30, a sufficient amount of the nitrogen-containing radical cannot be supplied onto the substrate 30 since the bond dissociation energy of nitrogen molecule is very large. More specifically, the bond dissociation energy of nitrogen molecule is approximately 9 eV. For this reason, high-speed growth of the semiconductor layer cannot be achieved by the method of generating the plasma of the gas mixture of nitrogen and hydrogen. More specifically, the growth rate of the group III nitride semiconductor layer is approximately 0.1 μm/hr to 0.3 μm/hr according to the method of generating the plasma of the gas mixture of nitrogen and hydrogen.

According to the embodiments, as explained above, the growth rate of the group III nitride semiconductor layer can be increased by 30% or more by making the gas mixture of nitrogen and hydrogen contain the appropriate quantity of the ammonia gas.

In contrast, according to the method of forming the III group nitride semiconductor layer by supplying the ammonia gas onto the substrate without using a plasma and by making the ammonia gas and the organic metal gas react with each other, the growth rate of the semiconductor layer can be raised since the bond dissociation energy of the ammonia molecule is smaller than that of nitrogen molecule. However, problems arise that the material costs are increased since a large quantity of ammonia is used, that costs for the corrosion-proof measure of parts of a manufacturing apparatus of a semiconductor device are increased since the high-concentration ammonia is used, that costs for building an ammonia abatement system are increased, that large-scale installations for supplying a liquefied ammonia are required, and the like.

According to the embodiments, the first gas is made to contain the appropriate quantity of the ammonia gas, and the plasma of the first gas is generated. For this reason, the quantity of use of the ammonia gas can be reduced and the above-mentioned problems can be solved.

Furthermore, according to the embodiments, the film formation temperature can be made lower than the temperature in a conventional manner of employing MOCVD using the high-concentration ammonia. Therefore, the high-quality group III nitride semiconductor layer can be formed at a lower temperature than the temperature in a case of employing MOCVD using the high-concentration ammonia gas.

As the pressure in the chamber 1 becomes higher, the first gas can be dissociated more hardly since the plasma density and the plasma electron temperature decrease qualitatively. Therefore, the method of increasing the supply quantity of the nitrogen-containing radicals to the substrate 30 by adding the ammonia gas to the gas mixture of nitrogen and hydrogen and raising the growth rate of the semiconductor layer, in the embodiments, is especially effective under a condition of a high pressure.

According to the embodiments, as explained above, the group III nitride semiconductor layer can be efficiently grown up by adding the ammonia gas to the supply gas containing the nitrogen gas.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a semiconductor device, the method comprising:
generating a plasma of a first gas containing a nitrogen gas and an ammonia gas;
supplying a second gas containing nitrogen-containing radicals produced by generating the plasma of the first gas, to a substrate;
supplying an organic metal gas containing a group III metallic element to the substrate; and
forming a group III nitride semiconductor layer on the substrate by the second gas and the organic metal gas.

2. The method of claim 1, wherein
the plasma of the first gas is generated at a position remoter from the substrate than a position where the organic metal gas is supplied to the substrate.

3. The method of claim 2, wherein
the second gas is supplied to the substrate through a mesh-like member disposed between the position where the plasma of the first gas is generated and the position where the organic metal gas is supplied.

4. The method of claim 1, wherein
the first gas further contains a hydrogen gas.

5. The method of claim 1, wherein
a concentration of the ammonia gas in the first gas is 1% to 10%.

6. The method of claim 1, wherein
a growth temperature in formation of the group III nitride semiconductor layer on the substrate is lower than 1000° C.

7. The method of claim 1, wherein
a pressure in formation of the group III nitride semiconductor layer on the substrate is 100 Pa to 10 kPa.

8. The method of claim 1, wherein
the organic metal gas contains at least one of aluminum, gallium, or indium.

9. A manufacturing apparatus of a semiconductor device, comprising:
a first gas supply unit which supplies a first gas containing a nitrogen gas and an ammonium gas;
a plasma generation mechanism which generates a plasma of the first gas supplied from the first gas supply unit;
a second gas supply unit which supplies an organic metal gas containing a group III metallic element; and
a susceptor on which a substrate supplied with the organic metal gas and a second gas containing nitrogen-containing radicals produced by generating the plasma of the first gas is placed.

10. The apparatus of claim 9, wherein
the plasma generation mechanism generates the plasma of the first gas at a position remoter from the substrate than a position of the second gas supply unit.

11. The apparatus of claim 10, further comprising:
a mesh-like member disposed between the position where the plasma of the first gas is generated by the plasma generation mechanism and the position of the second gas supply unit,
wherein the second gas is supplied to the substrate through the mesh-like member.

12. The apparatus of claim 9, wherein
the first gas further contains a hydrogen gas.

13. The apparatus of claim 9, wherein
the organic metal gas contains at least one of aluminum, gallium, or indium.
